(19) United States
(12) Patent Application Publication
(10) Pub. No.: US 2026/0367161 A1
(43) Pub. Date: Nov. 19, 2026

(54) DETECTING VOLTAGE READING DIVERGENCE OR VOLTAGE DROOP ISSUES USING TELEMATICS DATA

(71) Applicant: GM GLOBAL TECHNOLOGY OPERATIONS LLC, Detroit, MI (US)

(72) Inventors: Zijin Chen, Troy, MI (US); Guoqiang Lan, Austin, TX (US); Shelby Patzer, Pflugerville, TX (US); Jie Du, Bloomfield Hills, MI (US); Mahmoud Artima, Windsor (CA); Ryan B. Moulliet, Farmington Hills, MI (US); William Crowe, Farmington, MI (US); Hui Chen, Northville, MI (US); Paras Gandhi, Cumming, GA (US); Ali Talib, Austin, TX (US)

(73) Assignee: GM GLOBAL TECHNOLOGY OPERATIONS LLC, Detroit, MI (US)

(21) Appl. No.: 19/208,921

(22) Filed: May 15, 2025

(51) Int. Cl. G01R 31/3835; B60L 58/18; G01R 31/00; G01R 31/36

(52) U.S. Cl. CPC G01R 31/3835; B60L 58/18; G01R 31/007; G01R 31/3648; B60L 2240/547

(57) ABSTRACT

A method comprising: receiving data from a telematics system, the data comprising battery cell group voltage data from a plurality of measurement records, wherein each measurement record of the plurality of measurement records includes a timestamp including a date and time; calculating a time distance, to provide a calculated time distance, between at least two measurement records of the plurality of measurement records based on the timestamp of each of at least two measurement records to identify a measurement group based on the calculated time distance being within a time window, and repeating calculating the time distance to identify a plurality of measurement groups; and analyzing the data in the plurality of measurement groups to identify abnormal patterns and relationships with respect to data in one measurement group and data in a remainer of the plurality of measurement groups.

### INTRODUCTION

The technical field generally relates to battery packs and methods of identifying faulty battery pack components or entire battery packs.

Problems may arise during manufacturing and/or shipping of battery packs.

It is desirable to provide a method of detecting faulty battery pack components or entire battery packs. Furthermore, other desirable features and characteristics of the patentable variations will become apparent from the subsequent detailed description and the appended claims, taken in conjunction with the accompanying drawings and the foregoing introduction.

### SUMMARY

A number of variations may include a method including: receiving data from a telematics system, the data including battery cell group voltage data from a plurality of measurement records, wherein each measurement record of the plurality of measurement records includes a timestamp including a date and time; calculating a time distance, to provide a calculated time distance, between at least two measurement records of the plurality of measurement records based on the timestamp of each of at least two measurement records to identify a measurement group based on the calculated time distance being within a time window, and repeating calculating the time distance to identify a plurality of measurement groups; and analyzing the data in the plurality of measurement groups to identify abnormal patterns and relationships with respect to data in one measurement group and data in a remainer of the plurality of measurement groups.

A number of variations may include a method wherein the data further includes at least one of state of charge, temperature, or cell balance of a battery cell group, or mileage of a vehicle including the battery cell group.

A number of variations may include a method wherein the battery cell group voltage data is from the battery cell group that is in a battery pack in a vehicle, wherein the data is from a time after the vehicle was manufactured but before shipping to a dealership or from a time when the vehicle is at the dealership but before the vehicle is sold to a dealership customer.

A number of variations may include a method wherein the data includes date from a time after the vehicle is sold to a customer.

A number of variations may include a method further including calculating, for each cell group in the measurement group, a voltage deviation from a module voltage mean; selecting adjacent cell groups having opposite sign deviations, wherein a first cell group has a deviation greater than a threshold standard deviation and a second adjacent cell group has a deviation less than a threshold negative standard deviation; determining a ratio, to provide a determined ratio, of average absolute voltage deviation for the adjacent cell groups to the average absolute voltage deviation of remaining cell groups in a module; comparing the determined ratio to a first threshold value; and identifying the battery pack as having voltage divergence if the ratio exceeds the first threshold value.

A number of variations may include a method further including averaging the data from the measurement group.

A number of variations may include a method for detecting voltage reading divergence in an electric vehicle battery pack, the method including: receiving telematics data including voltage measurements from a plurality of cell groups in the electric vehicle battery pack; preprocessing the telematics data to group voltage measurements within a time window into a measurement group; determining a voltage deviation for each cell group from a module mean voltage within the measurement group; identifying a pair of adjacent cell groups within the measurement group, wherein one of the pair of the adjacent cell groups has a voltage deviation above a standard deviation threshold and another one of the pair of the adjacent cell groups has a voltage deviation below the negative standard deviation threshold; computing a ratio between an average absolute voltage deviation of the adjacent cell groups and an average absolute voltage deviation of remaining cell groups; and determining that a voltage divergence exists when the ratio exceeds a divergence threshold.

A number of variations may include a method, wherein determining that a voltage divergence exists includes evaluating the identified pair of adjacent cell groups for sign-reversed deviations, and further including: computing a first divergence indicator as a difference in voltage deviations of the adjacent cell groups; computing a second divergence indicator as a time-weighted cumulative sum of the first divergence indicator over a rolling 30-day window; applying a compensation factor to the second divergence indicator based on empirical battery system variance; classifying the voltage divergence as one of: (i) indicative of a connection issue including a weak weld or solder joint, or (ii) indicative of a component defect in a cell monitoring unit; and associating each classification with a detection threshold tailored to an identified cause, wherein a first category requires a smaller detection threshold due to low voltage deviation and a second category requires a larger detection threshold due to more significant deviation.

A number of variations may include a method, wherein the time window used for grouping measurements includes 600 seconds.

A number of variations may include a method, wherein the voltage deviation is determined from cumulative voltage measurements between pairs of sense lines connected to the plurality of cell groups.

A number of variations may include a method, wherein the divergence threshold is optimized using a Tree-structured Parzen Estimator.

A number of variations may include a method, further including classifying a root cause of the voltage divergence as a cell monitoring unit defect or sense line connection issue.

A number of variations may include a system for detecting electric vehicle battery pack issues using telematics data, the system including: an electric vehicle including a battery pack including a plurality of cell groups; a telematics communication module configured to transmit telemetry data including voltage, state of charge, temperature, cell balance, and mileage to a remote server; a computing device including an electronic processor and a non-transitory storage medium storing instructions that, when executed by the electronic processor, cause the computing device to: preprocess the telemetry data to group data points into measurement groups; compute voltage deviation metrics for each cell group; apply at least one diagnostic rule to identify divergent voltage patterns or drooping behavior in one or more cell groups; and output a diagnostic report identifying faulty or suspicious battery packs.

A number of variations may include a system, wherein the instructions further cause the computing device to: segment the telemetry data by vehicle identification number and time proximity to form consistent measurement groups; validate an integrity of each group by ensuring all expected cell groups have measurements; compute module-level statistics including mean and standard deviation of voltage; evaluate adjacent cell group voltage deviations relative to a module statistics; identify voltage divergence patterns using a Tree-structured Parzen Estimator to optimize a divergence detection threshold that maximizes a validation score based on real-world pack replacement and diagnostic code data; and assign severity scores to each battery pack based on a detected anomaly pattern and correlation with historical warranty events and critical diagnostic trouble codes.

A number of variations may include a system, wherein the computing device is configured to generate alerts for borderline fault cases recommending continued monitoring.

A number of variations may include a system, wherein the diagnostic report includes a severity classification score, a list of affected cell groups, and a recommendation for battery pack replacement or monitoring.

A number of variations may include a system, wherein the telematics communication module includes a vehicle-embedded transceiver connected to a satellite uplink or cellular network.

A number of variations may include a system, wherein the instructions further cause the computing device to apply exponential survival functions to derive validation scores for battery packs.

A number of variations may include a system, wherein the telemetry data includes timestamps corrected for time inconsistencies between data generation and reception.

A number of variations may include a system, wherein the computing device computes a ratio of daily voltage deviation droop to daily discharge rate as a composite feature.

### BRIEF DESCRIPTION OF THE DRAWINGS

The illustrative variations will hereinafter be described in conjunction with the following drawing figures, wherein like numerals denote like elements, and wherein:

FIG. 1 is a schematic illustration of a sense line and a cell monitoring unit for use with a battery pack according to a number of variations;

FIG. 2 is a graph of data showing adjacent cell group voltage readings diverging;

FIG. 3 is a schematic, with a portion enlarged, illustrating a sense line assembly and cell monitoring unit useful in a number of variations;

FIG. 4 is a schematic illustration of a plurality of cell groups and the voltage determined by a cell monitoring unit according to a number of variations;

FIG. 5 is a flow chart of a method according to a number of variations;

FIG. 6 illustrates a chart and a method of utilizing data collected within a time distance tolerance as part of the same measurement group according to a number of variations;

FIG. 7 is a chart illustrating voltage divergence of cell groups useful in methods according to a number of variations;

FIG. 8 is a graph illustrating a method of detecting voltage reading deviation issues in adjacent cell groups and identifying battery pack replacements when the adjacent cell group voltage deviation is above a threshold with respect to the rest of the cell groups in a module according to a number of variations;

FIG. 9 is a chart of diverging indicators useful in methods according to a number of variations;

FIG. 10 is a flow chart of a method of detecting cell monitoring unit issues according to a number of variations;

FIG. 11 is a graph illustrating cell voltage deviation indicative of cell monitoring unit issues useful in methods according to a number of variations;

FIG. 12 is a graph, illustrating cell voltage deviation indicative of issues not affecting electric vehicle performance, useful in methods according to a number of variations;

FIG. 13 aligns three graphs of data taken at various times including a chart of voltage deviation, a chart of open circuit voltage, and a chart of cell balancing data useful in methods according to a number of variations;

FIG. 14 is a flow chart of a method including using machine learning to classify which battery cells are faulty and which are not according to a number of variations;

FIG. 15 is a chart illustrating feature importance utilized to determine which battery cells are faulty and which are not, according to a number of variations;

FIG. 16 is a schematic illustration of a method of determining whether a battery pack should be recalled, or flagged as suspicious but not severely defective according to a number of variations; and

FIG. 17 is a schematic illustration of a system for processing telematics data according to a number of variations.

### DETAILED DESCRIPTION

The following detailed description is merely illustrative in nature and is not intended to limit the application and uses. Furthermore, there is no intention to be bound by any expressed or implied theory presented in the preceding introduction, brief description of the drawings, brief summary or the following detailed description.

The following is an overview of a system, components, and method for detecting battery pack issues according to a number of variations.

Electric vehicle battery packs may exhibit voltage reading divergence or voltage droop issues due to a variety of factors, including component defects, connection issues, and/or variations in battery cell behavior over time. A system and method have been developed to process telematics data, enabling early detection of these issues through diagnostic checkpoints established in both pre-sale and post-sale conditions. This system and method generate and analyzes time-series data which may include voltage, state of charge, temperature, cell balance, and mileage to identify abnormal patterns indicative of potential faults in battery packs. A suitable telematics system for receiving and/or processing data may include, but is not limited to, the OnStar system by General Motors.

To enhance the reliability of voltage measurement telematics data, a preprocessing method may be applied to address inconsistencies in recorded timestamps. Given that measurements within a vehicle may be recorded at different times than when they reach a data system, a method for grouping records within a specific time window may be used. A time distance calculation may be used to determine whether multiple records belong to a single measurement group. Within each group, multiple records for the same cell group may be averaged to derive a unique voltage reading. The calculated values include pack and module voltage mean, standard deviations, and cell group voltage deviations from the mean. Additional parameters such as odometer, state of charge, current, cell balance, and temperature may be integrated to enhance validation.

A method for detecting voltage reading divergence between adjacent cell groups may be employed. The process may involve selecting adjacent cell groups where one voltage deviation is above a standard deviation threshold while the other is below a negative standard deviation. A ratio of the average absolute cell-group voltage deviation of the adjacent groups to the remaining groups in a module is computed and compared against a threshold. If the ratio exceeds this threshold, the system identifies the presence of voltage divergence. The threshold may be optimized using a Tree-structured Parzen Estimator (TPE) algorithm to maximize a total validation score. The system may include a computing device including an electronic processor, a non-transitory storage media with written instructions executable by the electronic processor to carry out any act or functionality described herein.

To quantify the degree of voltage divergence, two indicators may be utilized. The first indicator may be the difference in adjacent voltage deviations within a measurement group. The second indicator may be a time period rolling cumulative sum of the first indicator, scaled using a compensation factor that accounts for variations in the system over time. For example, but not limited to, the second indicator may be a 30-day rolling cumulative sum of the first indicator, scaled using a compensation factor that accounts for variations in the system over time. This scaling factor may be determined based on empirical analysis of battery behavior and fault conditions.

Voltage divergence cases may be classified into two categories based on their underlying causes. In one category, adjacent cell groups exhibit opposite sign deviations, where the lower-positioned group has a lower voltage and the higher-positioned group has a higher voltage. This pattern may be associated with cell monitoring unit component defects, such as current leakage due to issues with capacitors or diodes on the cell monitoring unit board. In the other category, adjacent cell groups also show opposite sign deviations, but the voltage differences are more pronounced. These cases may be attributed to poor sense-line connections, including no welds between the sense line and cell tab or weak solder joints between the cell monitoring unit and sense line. Different detection thresholds may be applied to each category to optimize accuracy.

A workflow integrating the described ratios and indicators may be implemented to detect cell monitoring unit related voltage divergence issues. Specific thresholds are established to flag vehicle identification numbers (VINs) with significant voltage divergence. The validation score function may consider factors such as warranty claim history and the presence of diagnostic trouble codes (DTCs). The scoring model is designed to balance fault detection sensitivity with false positive reduction.

For detecting faulty battery cells exhibiting voltage droop, the system may analyze historical telemetry data to recognize patterns indicative of cell degradation. Some cells may recover from voltage droop through charging and balancing, while others may exhibit persistent deviations. Dynamic adjustment of the cell voltage deviation threshold allows the system to account for varying conditions such as open circuit voltage, cell balancing status, odometer readings, and temperature.

Feature engineering techniques may be applied to enhance fault detection accuracy. These features may include time-series derivatives of voltage deviation, open circuit voltage, cell balancing metrics, and/or odometer data. Composite features, such as the ratio of daily deviation droop to daily discharge rate, may be utilized to improve reliability. An initial preselection process identifies suspected faulty cells based on voltage deviation thresholds and deviation droop trends. Cells meeting these criteria undergo further analysis to confirm fault status.

Machine learning techniques, for example but not limited to, XGBoost models, may be used to classify faulty and non-faulty cells based on extracted features. The classification model may help reduce false positives and improve overall detection accuracy. Feature importance analysis provides insights into the key contributors to cell failure identification.

An automated process for optimizing preselection thresholds and machine learning hyperparameters may be incorporated. The optimization algorithm leverages the TPE approach to maximize the validation score across detected battery packs. The validation score accounts for various conditions, including warranty claims, critical diagnostic trouble codes, and historical battery replacement data. Different scoring weights are applied based on detection confidence levels to refine fault classification outcomes.

The integrated workflow enables automated classification of battery packs based on the severity of detected faults. For borderline cases, the system may recommend continued monitoring to improve certainty over time. This approach ensures early detection of potential failures while minimizing unnecessary interventions, ultimately enhancing the reliability and lifespan of electric vehicle battery packs.

Further detail of a system, components, and method for detecting battery pack issues according to a number of variations follows.

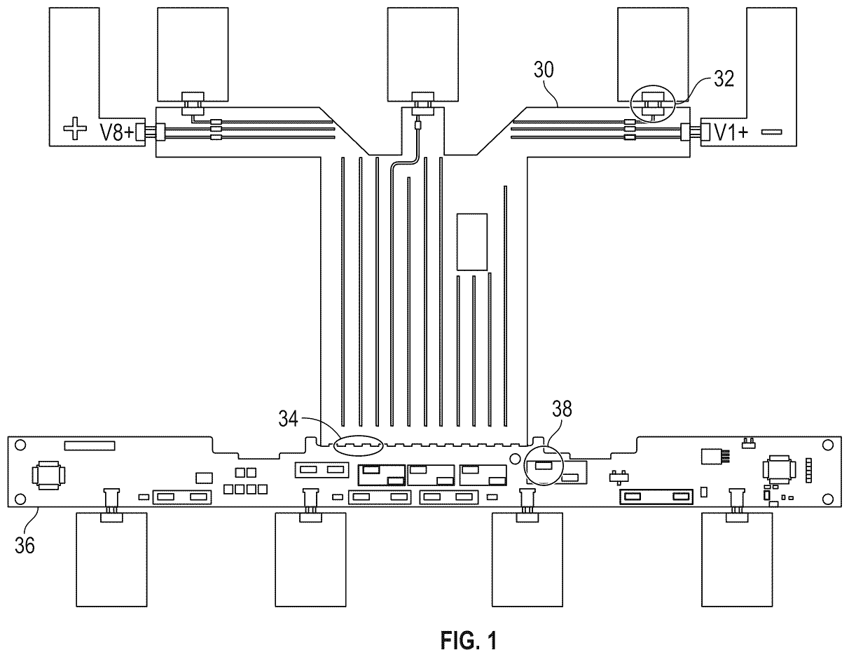

As shown in FIG. 1, a sense line 30 may be welded to a cell tab 32. The sense line 30 may also be connected to a cell monitoring unit 36 by solder joints 34. Known issues affecting cell monitoring unit reported values include no weld between the sense line 30 and the cell tab 32, solder joints 34 between the cell monitoring unit 36 and the sense line 30 that are weak or defective, or cell monitoring unit 36 defects including but not limited to cell monitoring unit components 38 such as defective capacitors or diodes that cause current leakage.

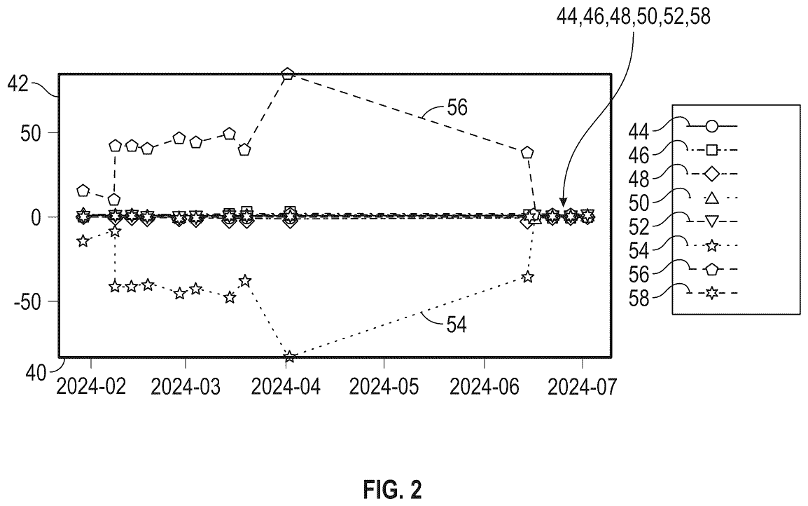

FIG. 2 is a graph of data showing adjacent cell group voltage readings diverging. The horizontal axis (x-axis) 40 includes a plurality of measurement dates, and the vertical axis (y-axis) 42 is voltage mean deviation for a plurality of cell groups. Line 44 represents cell group CG1, line 46 represents cell group CG2, line 48 represents cell group CG3, line 50 represents cell group CG4, line 52 represents cell group CG5, line 54 represents cell group CG6, line 56 represents cell group CG7, and line 58 represents cell group CG8.

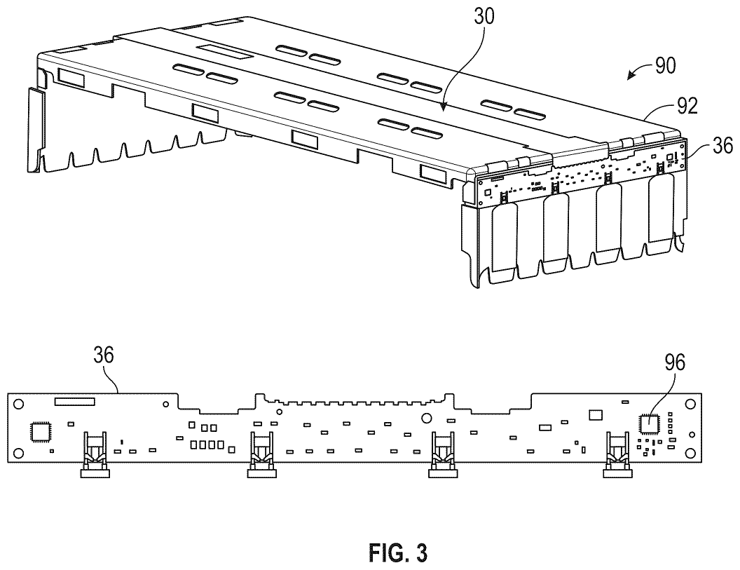

FIG. 3 is a schematic, with a portion enlarged, illustrating a sense line assembly 90 including the sense line 30, and the cell monitoring unit 36 supported by a substrate 92. The cell monitoring unit 36 may include a cell voltage sensing electronic chip 96. The cell monitoring unit 36 reports out the voltage and temperature of cells in a module. Components on the cell monitoring unit 36 including the cell voltage sensing electronic chip 96 may be faulty resulting in unreliable voltage readings for cell groups. Voltage reading errors may cause a cell balancing software in the system to make incorrect charging and discharging decisions, which can reduce vehicle performance and range, potentially leading to customer dissatisfaction and vehicle recalls.

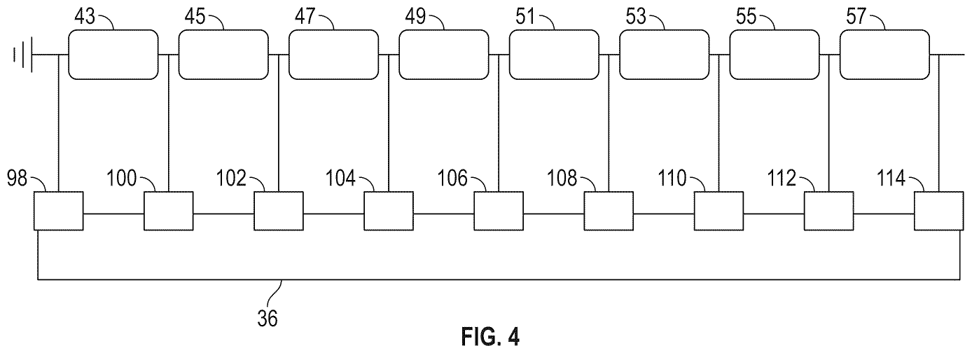

FIG. 4 is a schematic illustration of a plurality of cell groups and the voltage determined by a cell monitoring unit according to a number of variations. A plurality of cell groups may be evaluated using a cell monitoring unit 36. A plurality of cell groups is shown in FIG. 4 including box 43 representing cell group CG1, box 45 representing cell group CG2, box 47 representing cell group CG3, box 49 representing cell group CG4, box 51 representing cell group CG5, box 53 representing cell group CG6, box 55 representing cell group CG7, and box 57 representing cell group CG8. A method may include determining potential issues with cell monitoring unit 36 by comparing adjacent cell group voltages, wherein the CMU measures the cumulative voltage from ground up to each cell group.

Measurement points: V₀, V₁, . . . , V₈ correspond to cumulative voltages from ground, wherein
Vᵢ measure the total voltage
from ground to cell group i.
Theoretically,

$${V}_{i} = {V}_{0} + {\sum }_{1}^{i} {V}_{{CG}_{i}}$$

For a given cell group, the voltage is defined as:

V_{CGi}=Vᵢ−Vᵢ₋₁

If the reported voltage Vᵢ has an error Δ, then the erroneous reported voltage is:

$${V}_{i}^{read} = {V}_{i} + Δ$$

consequently, the cell group voltage with the air becomes:

$${V}_{CGi}^{read} = {V}_{CGi} + Δ$$

For the next cell group, the air will propagate as follows:

$${V}_{CGi + 1}^{read} = {V}_{CGi + 1} - Δ .$$

In a number of variations, a method of detecting issues in electric vehicle battery packs may include voltage, state of charge (SOC), temperature, cell balance and mileage time series data from telematics data, including at least one of pre-sale or post-sale diagnostic check points. Pre-sale diagnostic checks may include at a dealership before sale of the vehicle to a customer. The method may include simultaneously analyzing the time series data to identify abnormal patterns and relationships.

In a number of variations, a method of detecting issues in electric vehicle battery packs may include preprocessing telematics data, which may include two parts. First, there are inconsistencies from when a measurement was taken in the vehicle and the time that the data reaches a telematics data system. This leads to voltage measures that were taken simultaneously having different recorded measurement times in the data. To address this issue, a method may include grouping the records using a time window. The method may include calculating the time distance between records of a given VIN. If the time distance is within a stated tolerance and all expected cell groups have a recorded measurement, then those voltage measures may be considered as belonging to a single “measurement group.” Secondly, within the given measurement group, some cell groups might have multiple records, which may be averaged to get a unique value for each cell group. Then the pack and module voltage mean, standard deviations and cell group voltage deviation from mean may be calculated. Measurements such as odometer, state of charge, current, cell balance and temperature may be added for model purposes.

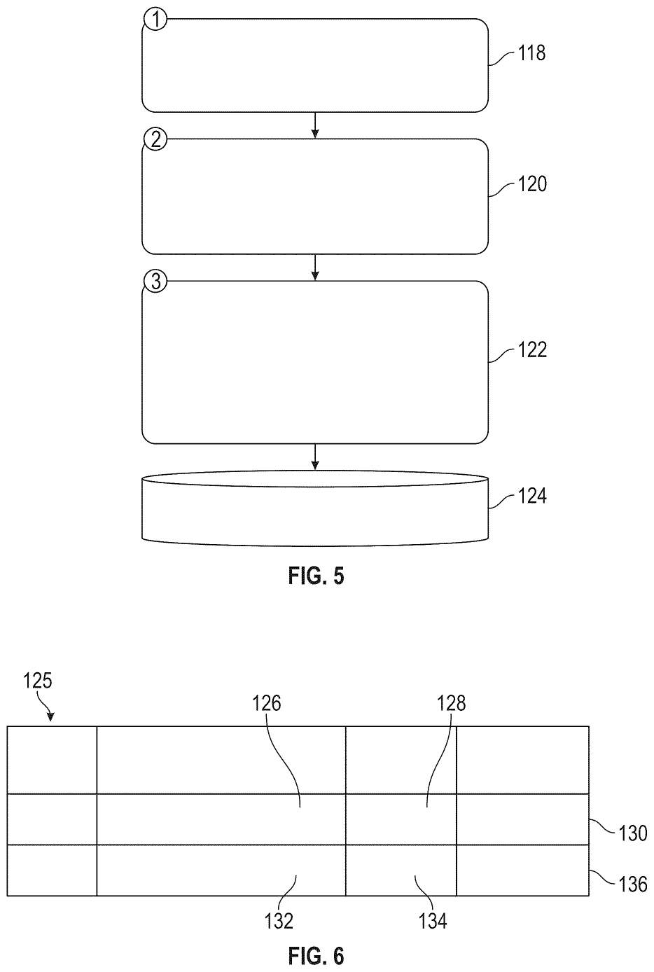

FIG. 5 is a flow chart of a method according to a number of variations. In step 118, cell group records are based on timestamp windows using a 600-second (10-minute) tolerance. This means records that occur within 10 minutes of each other are grouped as part of the same measurement group. In step 120, for each measurement group the module and pack mean voltages are computed, and the deviation of each cell group voltage from the module mean is calculated. In step 122, the data is enhanced by augmenting each measurement group with additional data regarding the odometer of the vehicle, state of charge, current, and temperature. In step 124, the data set collected is analyzed for divergent cases.

FIG. 6 illustrates a table showing two records that the system or method would consider being part of the same measurement group based upon data collected within a time distance tolerance as part of the same measurement group according to a number of variations.

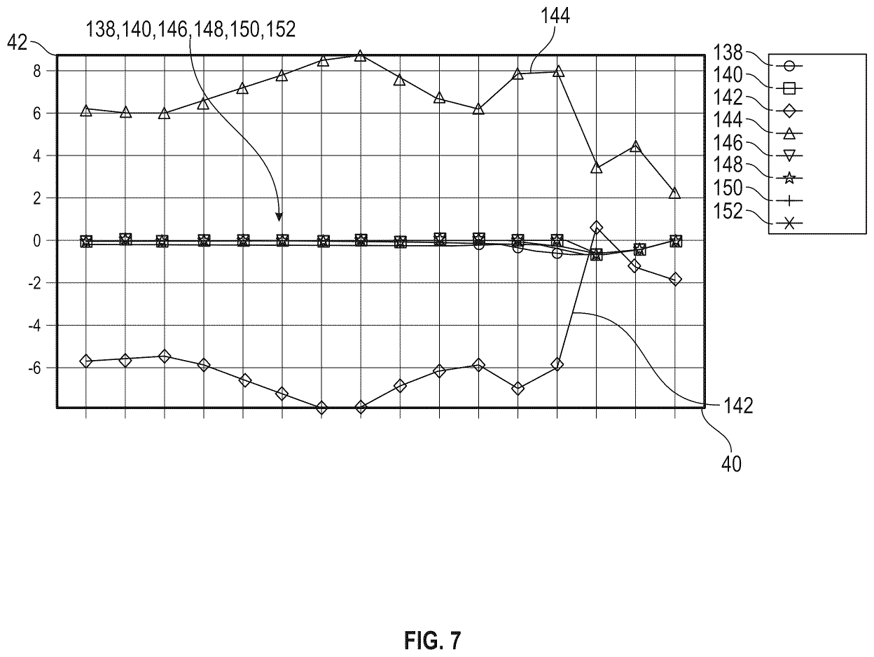

FIG. 7 is a graph illustrating voltage divergence of cell groups useful in methods according to a number of variations. The line plot displays cell group voltage deviations: wherein the X-axis 40: is measurement group (i.e., timestamps of grouped records), and the Y-axis 42 is deviation of each cell group's voltage from the module mean. Different numbered lines represent different cell groups (e.g., CG89 to CG96) wherein line 138 represents cell group CG89, line 140 represents cell group CG90, line 142 represents cell group CG91, line 144 represents cell group CG92, line 146 represents cell group CG93, line 148 represents cell group CG94, line 150 represents cell group CG95, and line 152 represents cell group CG96. The divergence of line 144 representing cell group CG92 that is raising and line 142 representing cell group CG91 that is falling signals potential voltage imbalance.

In a number of variations, a method may include an algorithmic approach to identify divergent voltage behaviors in adjacent cell groups (e.g., cell group i and i+1). The goal is to determine when adjacent groups show unusual deviation patterns, potentially indicating degradation or failure risk. The method may include, for any given measurement group (t), identify a pair of adjacent cell groups such that: one cell group's voltage deviation (CGVD) is above the standard deviation (STD), and the other group's CGVD is below the negative STD. This contrast highlights imbalance behavior localized between these two groups. The method may include calculating the average absolute CGVD for the selected adjacent pair and the rest of the module. To ensure that only the adjacent cell groups diverge within the module, a ratio is maintained between the average |CGVD| of the adjacent cell groups and the rest in a module. This ratio must be higher than a threshold (Th₀), expressed as:

$${σ}_{i}^{t} = \frac{\frac{1}{2} \vert C G V {D}_{i}^{t} - C G V {D}_{i + 1}^{t} \vert}{\frac{1}{n - 2} {\sum }_{k , k = i , k \neq i + 1}^{n} \vert C G V {D}_{k}^{t} \vert}$$

>Th₀, where t represents measurement group. Th₀ was optimized to be 3.9 using a Tree-structured Parzen Estimator (TPE) algorithm to maximize total validation score. This method helps isolate voltage anomalies to specific adjacent cell groups, which improves precision in diagnostics, early detection of localized degradation, and data quality for further predictive models.

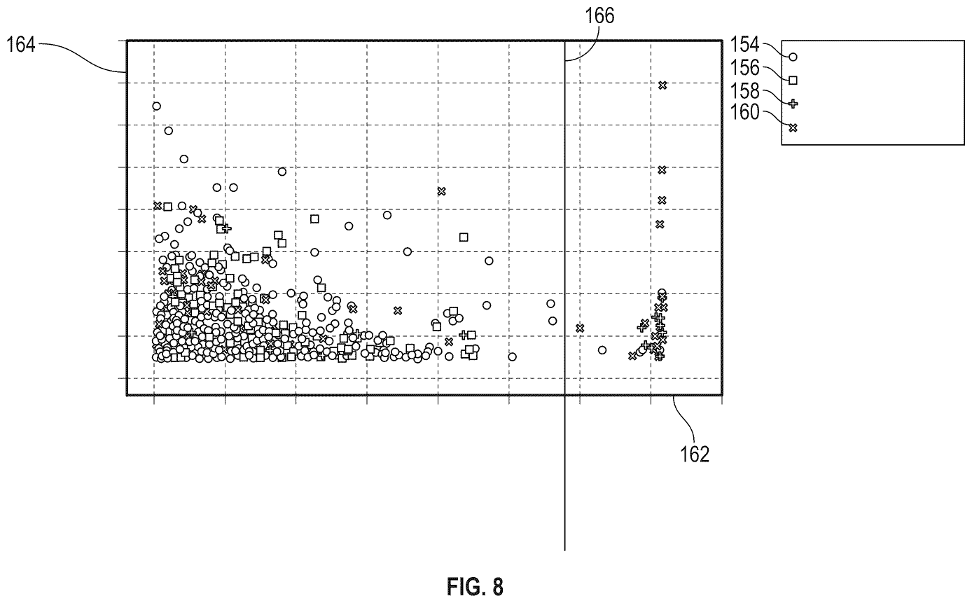

FIG. 8 is a graph illustrating a method of detecting voltage reading deviation issues in adjacent cell groups and identifying battery pack replacements when the adjacent cell group voltage deviation is above a threshold with respect to the rest of the cell groups in a module according to a number of variations. The x-axis 162 is Th₀, and the y-axis 164 is ΔCGDV. A first validation type 154, a second validation type 156, a third validation type 158, and a fourth validation type 160 are plotted in FIG. 8. Line 166 extends from 3.9 (Th₀ optimized) on the x-axis. For Th₀ greater than 3.9 the root causes of pack replacement are mainly cell monitoring unit issues.

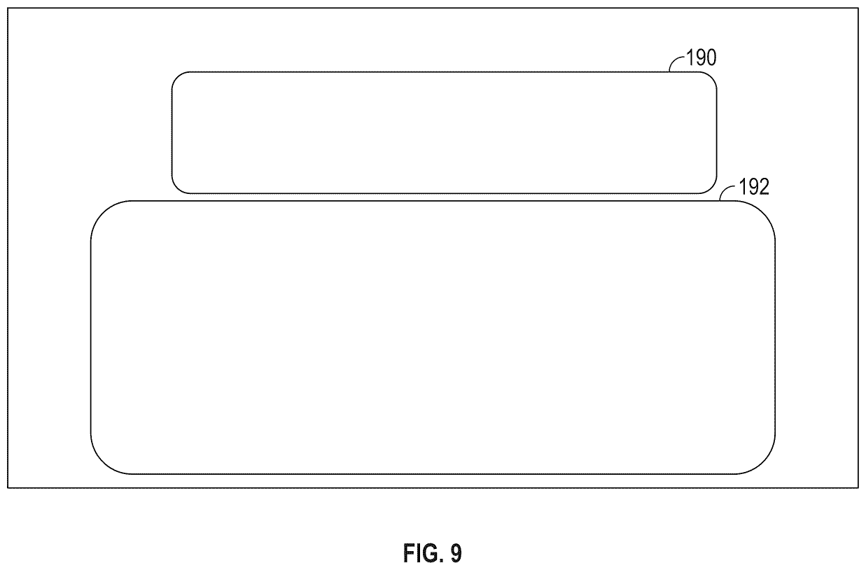

FIG. 9 shows two indicators that were designed to quantify the degree of divergence. The first indicator 190 is the difference in adjacent diverging voltage deviations for measurement group t, expressed as

$$Δ C G V {D}_{i}^{t} = \vert C G V {D}_{i}^{t} - C G V {D}_{i + 1}^{t} \vert .$$

The second indicator 192 is the 30-day rolling cumulative sum of

$${λ}_{i}^{t} Δ C G V {D}_{i}^{t} ,$$

where λ is a scaling factor (ranging from 0 to 1). The scaling factor is expressed as:

$${λ}_{i}^{t} = \{ \begin{matrix}1 - C {R}_{i}^{t} , & C {R}_{i}^{t} < 0.1 \\ 0 , & C {R}_{i}^{t} \geq 0.1\end{matrix}$$

and

$$C {R}_{i}^{t}$$

is the compensation rate for the adjacent cell groups (i, i+1) at each timestamp (t) using the formula:

$$C {R}_{i}^{t} = \vert \frac{C G V {D}_{i}^{t} + C G V {D}_{i + 1}^{t}}{2 MAX ( \vert C G V {D}_{i}^{t} \vert , \vert C G V {D}_{i + 1}^{t} \vert )} \vert .$$

In a number of variations, the method may classify divergence cases into two categories: first category: Cases where CGVDᵢ<0 and CGVDᵢ₊₁>0 (where i represents the cell group position index); and second category: Cases where CGVDᵢ>0 and CGVDᵢ₊₁<0. These categories are attributed to different root causes and require distinct thresholds for detection. There are primarily three root causes for voltage reading divergence related to CMU issues: first root cause: CMU component defects, such as current leakage due to capacitor or diode issues on the CMU board—first category; second root cause: No weld between the sense line and cell tab—second category; and third root cause: Weak solder joint between the CMU and sense line—second category.

The first root cause 1 (current leakage) (current leakage) typically leads to the lower-positioned cell group showing a lower voltage, while the higher-positioned group shows a higher voltage (first category), with a relatively small deviation (≤20 mV). In contrast, the second and third root causes (connection issues) usually result in significant deviations. Therefore, the first category requires a smaller threshold for detection, while the second category requires a larger threshold.

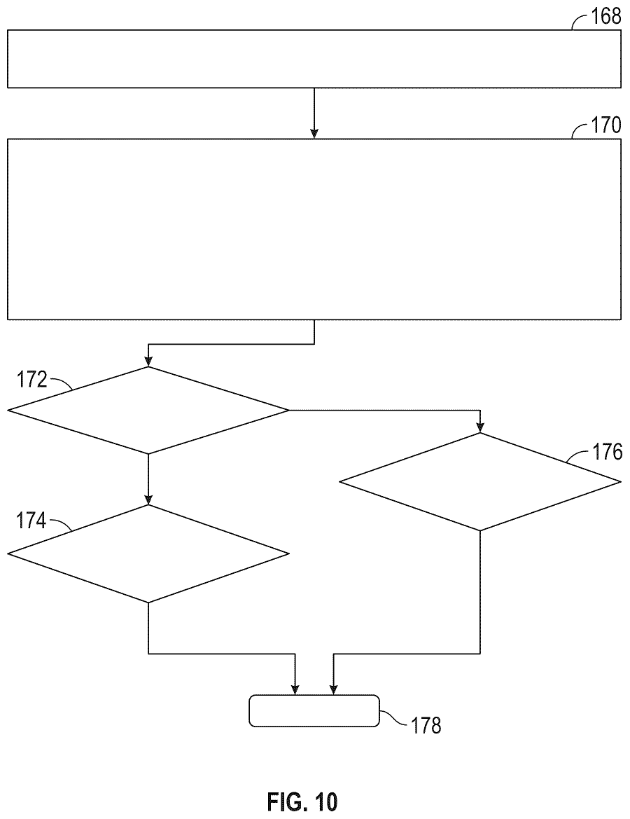

FIG. 10 is a flow chart of a method of detecting cell monitoring unit issues according to a number of variations. Step 168 includes selecting adjacent cell groups, i and i+1, where one voltage deviation (CGVD) is greater than a standard deviation (STD) and the other cell voltage deviation is less than the negative standard deviation (STD). Thereafter, step 170 includes ensuring that only the adjacent cell groups diverge in the model by maintaining a ratio between the average |CGVD| of the adjacent cell groups and the rest higher than a threshold (Th₀). Step 172 includes determining if CGVDᵢ is less than the 0 and CGVDᵢ₊₁ is greater than the 0, and if yes, at step 174 a determination if

$$Δ C G V {D}_{i}^{t} > {Th}_{1}$$

and if

$${λ}_{i}^{t} > {Th}_{2} ,$$

and if yes, a determination of diverging is made at step 178. At step 172, if CGVDᵢ is greater than the 0 and CGVDᵢ₊₁ is less than the 0, then at step 176 a determination of if

$$Δ {CGVD}_{i}^{t} > {Th}_{3}$$

and if

$${λ}_{i}^{t} > {Th}_{4} ,$$

if yes, a determination of diverging is made at step 178.

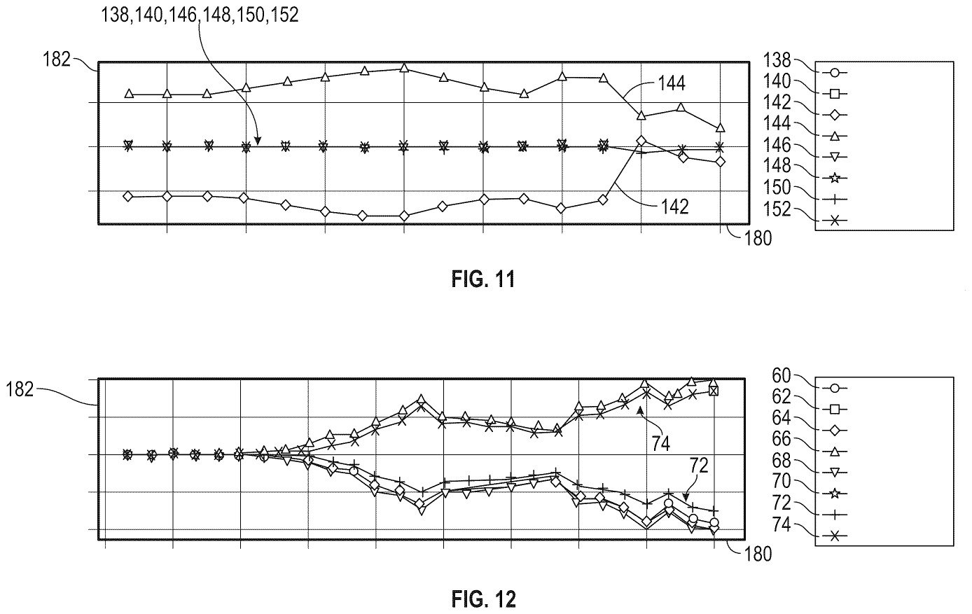

FIG. 11 is a graph illustrating cell voltage deviation indicative of cell monitoring unit issues useful in methods according to a number of variations.

FIG. 12 includes a graph of mean voltage deviation with respect to several cell groups. The horizontal axis (x-axis) 180 includes a plurality of measurement dates, and the vertical axis (y-axis) 182 is voltage deviation for a plurality of cell groups. Line 60 represents cell group CG33, line 62 represents cell group CG34, line 64 represents cell group CG35, line 66 represents cell group CG36, line 68 represents cell group CG37, line 70 represents cell group CG38, line 72 represents cell group CG39, and line 74 represents cell group CG40. The plot of cell group voltages is indictive of other issues not affecting electric vehicle performance.

Specific thresholds (e.g., Th0, Th1, Th2, Th3, Th4) were established to identify VINs with serious voltage divergence issues. VINs were selected when indicators exceeded these thresholds a certain measurement group. The thresholds were optimized using a Tree-structured Parzen Estimator (TPE) algorithm to maximize a total validation score, given by

$${S}_{total} = {\sum }_{i = k}^{n} {S}_{{pack}_{i}}$$

where n is the number of detected battery packs, S_{pack} represents the score for an individual pack and it depends on validation type, the presence of a pack replacement warranty claim, and the presence of critical Diagnostic Trouble Codes (cDTCs). It is shown as follows:
pack replace match cDTC: S_{pack}=1
pack replace no cDTC: S_{pack}=1
pack replace not match cDTC: S_{pack}=0.5
match_cDTC: S_{pack}=e^{-b1*odometer}
no_cDTC: S_{pack}=e^{-b2*odometer}−1
not_match_cDTC: S_{pack}=0.5e^{-b3*odometer}.

For packs under match cDTC, no cDTC and not match cDTC validation types, the validation score is modeled using an exponential survival function. For all packs detected with match cDTC, the exponential survival function is fitted to determine b1. Similarly, b2 and b3 are derived for packs categorized as no cDTC and not match cDTC, respectively.

In a number of variations, a method may include detecting faulty battery cells in an electric vehicle battery pack, developed based on an in-depth understanding of battery physics and chemistry, including: identifying cell voltage droop behavior within the battery pack; recognizing that some battery cells recover from voltage droop through charging or cell balancing; and/or requiring dynamically adjustment of the cell voltage deviation threshold to identify faulty battery cells under varying conditions, including open circuit voltage (OCV), cell voltage balancing status, odometer readings, and temperature. Many battery packs exhibit cell voltage droop behavior, but some can even recover through charging or cell balancing.

In a number of variations, a method may include not only analyzing current conditions but also may include using time-series battery monitoring telemetry data by incorporating prior conditions and deriving key metrics from voltage deviations, OCV, cell voltage balancing, and odometer data over time. These derived metrices may be helpful for accurately detecting true faulty battery cells. The main metrices are shown as below (wherein i denotes the cell number, identifying a specific battery cell, while t indicates the measurement time group, corresponding to a specific point in the monitoring timeline).
a) Voltage deviation related features:
   Voltage deviation:

$${VD}_{i}^{t}$$

Prior voltage deviation:

$${VD}_{i}^{t - 1}$$

First derivative of deviation (daily deviation droop):

$$\frac{{dVD}_{i}^{t}}{dt}$$

Prior daily deviation droop:

$$\frac{{dVD}_{i}^{t - 1}}{dt}$$

Second derivative of deviation:

$$\frac{{d}^{2} {VD}_{i}^{t}}{{dt}^{2}}$$

b) OCV related features:
   OCV:

$${V}_{i}^{t}$$

Prior OCV:

$${V}_{i}^{t - 1}$$

First derivative of Vᵢ (daily OCV droop):

$$\frac{{dV}_{i}^{t}}{dt}$$

Prior daily OCV droop:

$$\frac{{dV}_{i}^{t - 1}}{dt}$$

Mean OCV of other cells in the same module
Mean prior OCV of other cells in the same module
Mean daily OCV droop of other cells in the same module
c) Cell balancing related features:
   Cell balancing mean: CBM^{t}
   Prior CBM: CBM^{t-1}
   First derivative of CBM:

$$\frac{{dCBM}^{t}}{dt}$$

d) Odometer related features:
   Odometer: ODO^{t}
   Daily odometer:

$$\frac{{dODO}^{t}}{dt}$$

e) Temperature related features:
   Pack temperature: T^{t}
f) Furthermore, the invention combines features, such as the ratio of daily deviation droop to daily discharge rate

$$( {σ}_{i}^{t} = \frac{{dVD}_{i}^{t}}{{dV}_{i}^{t}} ) ,$$

to develop more robust and reliable indicators for detecting faulty battery cells.

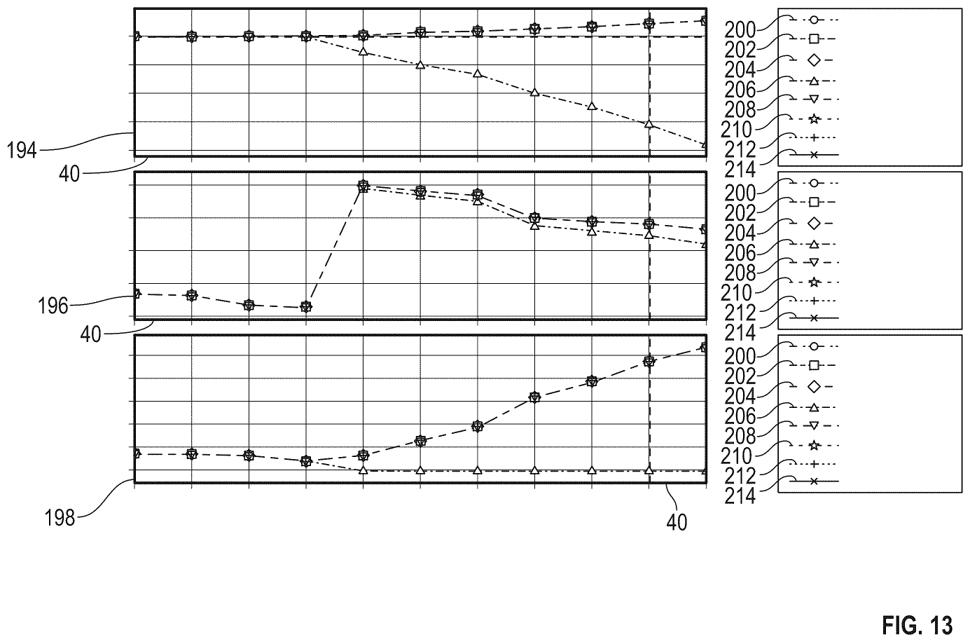

In FIG. 13, three charts are shown wherein one cell group deviates from other cell groups with respect to a feature measured to predict battery pack issues. In each of the three charts different numbered lines represent different cell groups (e.g., CG49 to CG56) wherein line 200 represents cell group CG49, line 202 represents cell group CG50, line 204 represents cell group CG51, line 206 represents cell group CG52, line 208 represents cell group CG53, line 210 represents cell group CG54, line 212 represents cell group CG55, and line 214 represents cell group CG56. In each of the three charts the X-axis 40: is measurement group (i.e., timestamps of grouped records). In one chart the Y-axis 194 is deviation of each cell group's voltage from the module mean. In one chart the Y-axis 196 is open circuit voltage. In one chart the Y-axis 198 is cell balancing remaining amp-hours of battery.

In a number of variations, a method may include preselecting suspected battery cells exhibiting voltage droop behavior using the following criteria:
a) VDᵢ<Th0 (Voltage deviation is below a threshold).
b) prior and current daily droop of VDᵢ satisfying

$$\frac{{dVD}_{i}}{dt} \leq Th 1.$$

c) a condition to ensure detection of cells under discharging, where the prior and current daily droop of open circuit voltage (OCV) meet

$$\frac{{dV}_{i}}{dt} \leq 0.$$

This condition helped to remove many false alarms because in charging state, voltage deviation is much more erratic.

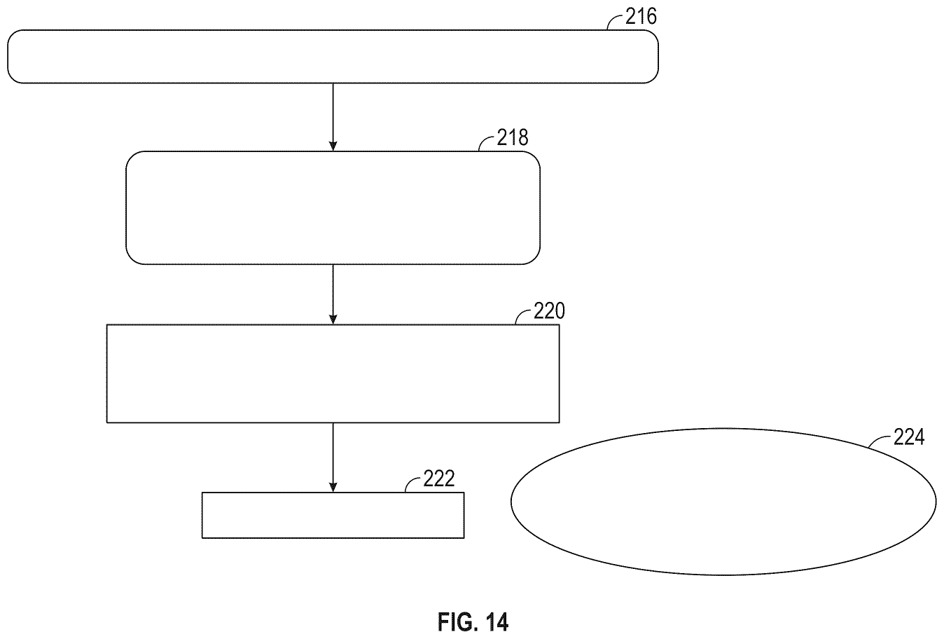

FIG. 14 is a method flow chart which at box 216 may include selecting cell group, i, having a voltage deviation (VD) that is less than a negative standard deviation (<-STD). At box 218, setting thresholds for voltage deviations (VDᵢ) and daily droop of voltage deviations (VDᵢ), to pre-select suspected cells with voltage droop issues. At box 220, utilizing a machine learning module, such as XGBoost, to classify which cells are truly faulty and which are not, and to identify other features such as open circuit voltage, voltage deviation, daily droop of open circuit voltage and voltage deviation, cell balancing, daily odometer readings, and temperature that contribute to detecting faulty battery cells. At box 222, making a final detection as to whether or not which cells are faulty.

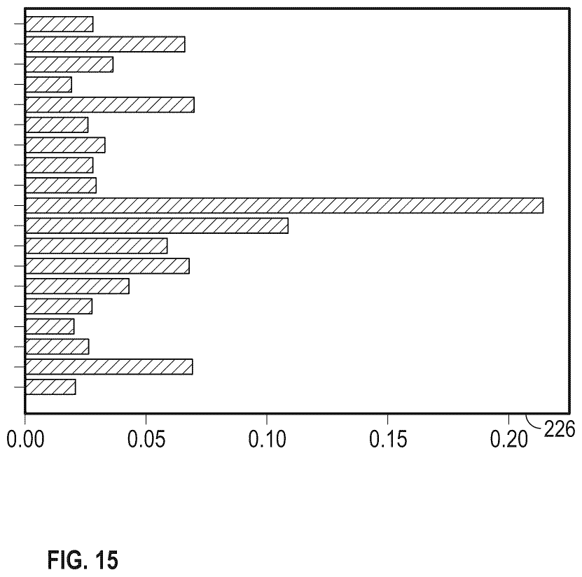

FIG. 15 is a chart illustrating feature importance utilized to determine which battery cells are faulty and which are not, according to a number of variations. The X-axis 226 is feature importance increasing in value from the Y-axis 228. Various features impacting battery cell performance are plotted on the Y-axis 228. Pack temperature is represented by bar 230, first derivative of cell balancing mean is represented by bar 232, prior cell balancing mean is represented by bar 234, ratio of voltage deviation of suspected cells to others is represented by bar 236, a 15 day rolling maximum of daily voltage droop is represented by bar 238, prior daily voltage deviation droop is represented by bar 240, prior daily open circuit voltage droop is represented by bar 242, mean daily open circuit voltage droop of other cells is represented by bar 244, daily odometer reading is represented by bar 246, mean prior open circuit voltage of other cells is represented by bar 248, mean open circuit voltage of other cells is represented by bar 250, prior open circuit voltage is represented by bar 252, cell balancing mean is represented by bar 254, ratio of daily voltage deviation droop for daily open circuit voltage droop is represented by bar 256, voltage deviation is represented by bar 258, second derivative of voltage deviation is represented by bar 260, voltage deviation droop is represented by bar 262, and open circuit voltage is represented by bar 264, and daily open circuit voltage droop is represented by bar 266.

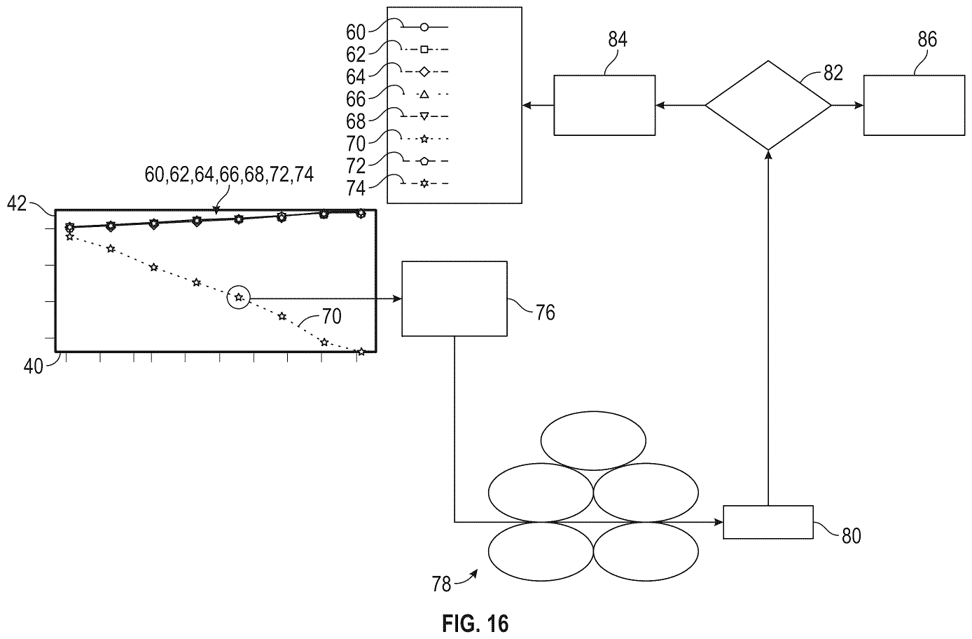

FIG. 16 includes a graph of voltage deviation with respect to several cell groups. The horizontal axis (x-axis) 40 includes a plurality of measurement dates, and the vertical axis (y-axis) 42 is voltage deviation for a plurality of cell groups. Line 60 represents cell group CG33, line 62 represents cell group CG34, line 64 represents cell group CG35, line 66 represents cell group CG36, line 68 represents cell group CG37, line 70 represents cell group CG38, line 72 represents cell group CG39, and line 74 represents cell group CG40. The increasing voltage deviation cell group CG38 with time makes it suspect of being faulty. The system or method may conduct feature monitoring at box 78 of the suspected cell with respect to voltage deviation, temperature, cell balancing, open circuit voltage, and odometer. At box 80, a classifier may be used to calculate a probability that the suspected cell group is faulty. At box 82, the calculated probability is compared to a probability threshold, for example greater than 0.6, and if the calculated probability is greater than the probability threshold the suspected cell group is determined to be faulty at box 86, and if the calculated probability is less than the probability threshold and greater than or equal to a near boundary detection probability threshold, from example greater than or equal to 0.5, the process is continued with continued monitoring at box 84 being conducted until the calculated probability is greater than 0.6 (being detected), or not being preselected (being normal).

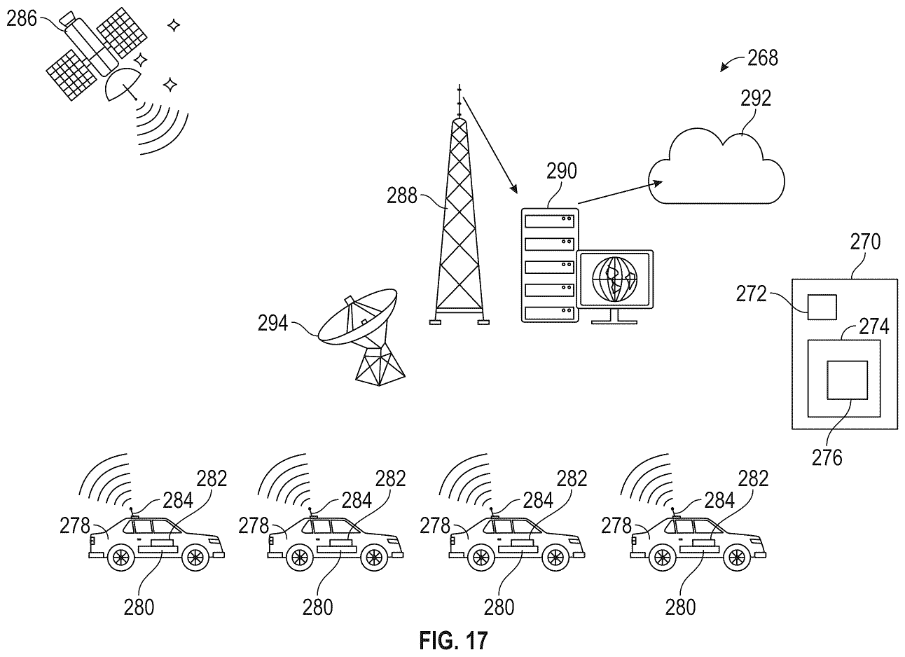

FIG. 17 is a schematic illustration of a system 268 for processing telematics data according to a number of variations. The system 268 may include at least one computing device 270. The at least one computing device 270 may include an electronic processor 272, at least one non-transitory storage media 274 having at least one set of written instructions 276 executable by the electronic processor 272 to carry out any of the steps, acts, or functionality described herein. At least one electric vehicle 278 including at least one battery pack 280 operatively connected to an electric propulsion system 282 for propelling the at least one electric vehicle 278. The at least one electric vehicle 278 may also include a telecommunication system 284 for communicating with a satellite 286 and/or a cellular network 288. Cellular network 288 may communicate with a server 290 which may communicate with an internet system 292. The internet system 292 and/or the cellular network 288 may communicate with a satellite uplink and/or downlink system 294, which may communicate with the satellite 286. The at least one electric vehicle 278 may include numerous vehicles for example, but not limited to, more than 100 vehicles that the satellite 286 may communicate with at substantially the same time to receive data described herein. The system 268 allows the satellite 286 to retrieve data from the at least one battery pack 280 and communicate the same to the at least one computing device 270 for processing the data in any manner described herein.

While at least one variation has been presented in the foregoing detailed description, it should be appreciated that a vast number of variations exist. It should also be appreciated that the variation or variations are only examples, and are not intended to limit the scope, applicability, or configuration of the disclosure in any way. Rather, the foregoing detailed description will provide those skilled in the art with a convenient road map for implementing the illustrative variation or variations. It should be understood that various changes can be made in the function and arrangement of elements without departing from the scope of the disclosure as set forth in the appended claims and the legal equivalents thereof.

1. A method comprising:
receiving data from a telematics system, the data comprising battery cell group voltage data from a plurality of measurement records, wherein each measurement record of the plurality of measurement records includes a timestamp including a date and time;
calculating a time distance, to provide a calculated time distance, between at least two measurement records of the plurality of measurement records based on the timestamp of each of at least two measurement records to identify a measurement group based on the calculated time distance being within a time window, and repeating calculating the time distance to identify a plurality of measurement groups; and
analyzing the data in the plurality of measurement groups to identify abnormal patterns and relationships with respect to data in one measurement group and data in a remainder of the plurality of measurement groups, wherein the battery cell group voltage data comprise cumulative voltage measurements acquired at sense lines connected to a plurality of battery cell groups, and wherein analyzing the data comprises deriving respective cell-group voltages from differences between cumulative voltage measurements of adjacent sense lines and outputting a diagnostic indication identifying, based on an identified abnormal pattern, at least one of a cell monitoring unit component defect or a sense-line connection issue.

2. The method as set forth in claim 1 wherein the data further comprises at least one of state of charge, temperature, or cell balance of a battery cell group, or milage of a vehicle including the battery cell group.

3. The method as set forth in claim 2 wherein the battery cell group voltage data is from the battery cell group that is in a battery pack in the vehicle, wherein the data is from a time A after the vehicle was manufactured but before shipping to a dealership or from a time B when the vehicle is at the dealership but before the vehicle is sold to a customer.

4. The method as set forth in claim 2 wherein the battery cell group voltage data is from the battery cell group that is in a battery pack in the vehicle, wherein the data includes data from a time C after the vehicle is sold to a customer.

5. The method as set forth in claim 4 further comprising calculating, for each cell group in the measurement group, a voltage deviation from a module voltage mean;
selecting adjacent cell groups having opposite sign deviations, wherein a first cell group has a deviation greater than a threshold standard deviation and a second adjacent cell group has a deviation less than a negative threshold standard deviation;
determining a ratio, to provide a determined ratio, of average absolute voltage deviation for the adjacent cell groups to the average absolute voltage deviation of remaining cell groups in a module;
comparing the determined ratio to a first threshold value; and
identifying the battery pack as having voltage divergence if the ratio exceeds the first threshold value.

6. The method as set forth in claim 1 further comprising averaging the data from the measurement group.

7. A method for detecting voltage reading divergence in an electric vehicle battery pack, the method comprising:
receiving telematics data comprising voltage measurements from a plurality of cell groups in the electric vehicle battery pack;
preprocessing the telematics data to group voltage measurements within a time window into a measurement group;
determining a voltage deviation for each cell group from a module mean voltage within the measurement group;
identifying a pair of adjacent cell groups within the measurement group, wherein one of the pair of the adjacent cell groups has a voltage deviation above a standard deviation threshold and another one of the pair of the adjacent cell groups has a voltage deviation below a negative standard deviation threshold;
computing a ratio between an average absolute voltage deviation of the adjacent cell groups and an average absolute voltage deviation of remaining cell groups;
determining that a voltage divergence exists when the ratio exceeds a divergence threshold;
wherein determining that the voltage divergence exists comprises evaluating the pair of adjacent cell groups for sign-reversed deviations, and further comprising:
computing a first divergence indicator as a difference in voltage deviations of the adjacent cell groups;
computing a second divergence indicator as a time-weighted cumulative sum of the first divergence indicator over a rolling 30-day window;
applying a compensation factor to the second divergence indicator based on empirical battery system variance;
classifying the voltage divergence as a classification as one of: (i) indicative of a component defect in a cell monitoring unit, or (ii) indicative of a connection issue including a weak weld or solder joint;
associating the classification with a detection threshold tailored to an identified cause, wherein a first category requires a smaller detection threshold due to low voltage deviation and a second category requires a larger detection threshold due to more significant deviation; and
outputting, based on the classification, an alert identifying the electric vehicle battery pack for replacement or continued monitoring.

8. The method of claim 7, wherein, for the first category, a lower-positioned cell group of the pair of adjacent cell groups exhibits a lower voltage than a higher-positioned cell group of the pair of adjacent cell groups, and a voltage deviation associated with the first category is less than or equal to 20 mV.

9. The method of claim 7, wherein the time window used for grouping measurements comprises 600 seconds.

10. The method of claim 7, wherein the voltage deviation is determined from cumulative voltage measurements between pairs of sense lines connected to the plurality of cell groups.

11. The method of claim 7, wherein the divergence threshold is optimized using a Tree-structured Parzen Estimator.

12. The method of claim 7, wherein the component defect in the cell monitoring unit comprises current leakage caused by a capacitor or diode, and the connection issue comprises a weak solder joint between the cell monitoring unit and a sense line.

13. A system comprising:
an electric vehicle comprising a battery pack including a plurality of cell groups;
a telematics communication module configured to transmit telemetry data including voltage, state of charge, temperature, cell balance, and mileage to a remote server;
a computing device comprising an electronic processor and a non-transitory storage medium storing instructions that, when executed by the electronic processor, cause the computing device to:
preprocess the telemetry data by segmenting the telemetry data by vehicle identification number and time proximity to group data points into measurement groups;
compute voltage deviation metrics for each cell group;
apply at least one diagnostic rule to identify divergent voltage patterns or drooping behavior in one or more cell groups;
validate an integrity of each group by ensuring all expected cell groups have measurements;
compute module-level statistics including mean and standard deviation of voltage;
evaluate adjacent cell group voltage deviations relative to a module-level statistics;
identify voltage divergence patterns using a Tree-structured Parzen Estimator to optimize a divergence detection threshold that maximizes a validation score based on real-world pack replacement and diagnostic code data;
assign a severity score to the battery pack based on a detected anomaly pattern and correlation with historical warranty events and critical diagnostic trouble codes; and
output a diagnostic report identifying faulty or suspicious battery packs and specifying, based on a severity score, a battery-pack replacement or continued-monitoring recommendation.

14. The system of claim 13, wherein the instructions further cause the computing device to calculate a probability that a battery pack is faulty, classify the battery pack as defective when the probability is greater than 0.6, recommend continued monitoring when the probability is at least 0.5 and no greater than 0.6, and classify the battery pack as not defective when the probability is less than 0.5.

15. The system of claim 13, wherein the computing device is configured to generate alerts for borderline fault cases recommending continued monitoring.

16. The system of claim 13, wherein the diagnostic report includes a severity classification score, a list of affected cell groups, and a recommendation for battery pack replacement or monitoring.

17. The system of claim 13, wherein the telematics communication module comprises a vehicle-embedded transceiver connected to a satellite uplink or cellular network.

18. The system of claim 13, wherein the instructions further cause the computing device to apply exponential survival functions to derive validation scores for battery packs.

19. The system of claim 13, wherein the telemetry data includes timestamps corrected for time inconsistencies between data generation and reception.

20. The system of claim 13, wherein the computing device computes a ratio of daily voltage deviation droop to daily discharge rate as a composite feature.
